(19) United States
(12) Patent Application Publication
(10) Pub. No.: US 2026/0201560 A1
(43) Pub. Date: Jul. 16, 2026

(54) SUBSTRATE RETAINER

(71) Applicant: Black Semiconductor Netherlands B.V., Zoetermeer (NL)

(72) Inventors: Richard van Rijn, Zoetermeer (NL); Michele Buscema, Zoetermeer (NL); Matthew David Barnes, Zoetermeer (NL); Kris Charles Leask, Zoetermeer (NL); Mohammad Sohail Shaik, Zoetermeer (NL)

(73) Assignee: Black Semiconductor Netherlands B.V., Zoetermeer (NL)

(21) Appl. No.: 19/135,094

(22) PCT Filed: Dec. 15, 2023
(86) PCT No.: PCT/NL2023/050662

§ 371 Date: Jun. 3, 2025

(30) Foreign Application Priority Data
Dec. 16, 2022 (NL) 2033744

(51) Int. Cl. C23C 16/458; H10P 72/76

(52) U.S. Cl. CPC C23C 16/4583; C23C 16/4581; H10P 72/7611

(57) ABSTRACT

A retainer for holding a substrate during chemical vapor deposition, CVD, processing, the retainer having:
a first surface configured to form a counter surface for an exposure surface of the substrate;
a second surface, substantially parallel to the counter surface and arranged at a distance, d, from the counter surface, the second surface arranged for supporting the substrate;
a third surface, arranged at an angle to the second surface, the third surface forming an edge confining movement of the substrate.

### FIELD OF THE INVENTION

The present invention relates to a substrate retainer, in particular to a substrate retainer for supporting a substrate during chemical vapor deposition, CVD, processing, and to methods of manufacturing such retainer. The retainer is in particular suitable for low pressure chemical vapor deposition, LP-CVD, of thin graphene films.

### BACKGROUND ART

Graphene has been observed as having specific properties, for example relating to electrical and/or chemical properties. The specific properties of graphene renders it very interesting for a wide range of applications, including electronics, lasers, bio-sensors, photonic switches, light emitting diodes (LED), infrared sensors, protective coatings, hydrogen storage and energy storage.

Chemical vapor deposition (CVD) is conventionally used to produce graphene layers and thin films. In such known CVD processes, a surface of a metal substrate is exposed to a carbon-containing precursor gas, such as methane, ethane, ethylene or benzene, which results in adsorption of precursor gas molecules on the surface of the metal substrate. The adsorbed precursor gas molecules then decompose to form carbon, which remain on the surface of the metal substrate and form graphene. The process may also involve decomposition of the precursor gas prior to adsorption on the surface, and subsequent deposition of resulting carbon atoms. Any volatile components are typically pumped away by a vacuum pumping system. Certain methods of making graphene film using CVD involve the use of a metal substrate formed from metals such as nickel or copper. This is at least in part because both nickel and copper allow graphene to grow epitaxially on certain crystal facets on their surface.

Graphene is conventionally produced by CVD processes performed at high temperature and low pressure, so called low pressure CVD, LP-CVD. It has been observed that in such processes, metal atoms, i.e., copper or nickel, tend to evaporate from the surface of the metal substrate. This leads to an uneven substrate surface which in turn may result in wrinkled or incomplete formation of graphene on that surface, since the surface morphology of the substrate surface would be built into the graphene. This may hamper the formation of a large area of continuous graphene. Also, subsequent transfer of the wrinkled and/or incomplete graphene layer onto another substrate would lead to a resulting graphene layer which may also be wrinkled and/or experiencing varying strain throughout the layer. Such methods may also provide graphene layers with small grain sizes, which can be detrimental to carrier mobility, for example because the crystal lattices of adjacent grains typically do not align. Small grain sizes may result from, for example, a high and/or nonuniform nucleation density at formation or poor crystal alignment at formation or a combination thereof.

Known measures for addressing, or at least reducing, the above described problems related to evaporation of metal atoms from the metal exposure substrate, on which the graphene layer is to be formed, include using at least partially enclosed substrate holders and/or providing a counter surface opposite to the exposure surface of the metal substrate, in order to prevent or at least reduce a net evaporation of the metal atoms from the deposition region.

Methods of using a counter surface opposite to the exposure substrate are described in WO 2014/033282 A1. These methods have been seen to efficiently prevent net copper evaporation.

However, the above cited publication does not provide an efficient, highly accurate and fast manner of realizing a well defined distance between the metal substrate and the counter surface. Also, conventional retainers or substrate supports are not suitable for direct implementation in an industrial production line, such as in a semiconductor fab.

### SUMMARY OF THE INVENTION

It is an object of the invention to provide a substrate retainer providing a well-defined distance between the exposure surface of the metal substrate and the counter surface.

It is a further object to provide a substrate retainer which can be handled by conventional production line and/or semiconductor fab systems, in particular as to transporting the retainer through the fab or production line and performing low pressure chemical vapor deposition, LP-CVD, on a substrate carried by the retainer.

This is achieved by a substrate retainer as defined in claim 1.

According to a first aspect, a retainer for holding a substrate during chemical vapor deposition, CVD, processing, the retainer comprising:
a first surface configured to form a counter surface relative to an exposure surface of the substrate;
a second surface, substantially parallel to the counter surface and arranged at a distance, d, from the counter surface, the second surface arranged for supporting the substrate;
a third surface, arranged at an angle to the second surface, the third surface forming an edge for confining movement of the substrate.

The retainer may be configured such that a reaction cavity is formed between the exposure surface of the substrate and the counter surface when the substrate is supported by the retainer.

That is, the substrate should be positioned up-side down on the retainer, with its exposure surface facing the counter surface. The counter surface will then be located opposite to the exposure surface of the substrate. The cavity hence formed forms the reaction cavity, or reaction space, where the chemical processes involved in chemical vapor deposition take place.

The retainer is configured to support the substrate with the substrate resting on the second surface under the force of gravity. Hence, the retainer does not require the use of any fastening means, such as screws, clamps, and/or glue for maintaining the substrate on the retainer.

Due to this reaction cavity, net evaporation of metal atoms, such as copper, from the exposure surface of the substrate, may be counteracted.

The distance, d, between the counter surface and the second surface is a pre-defined distance, typically in the range of a few hundreds of a mm to a few mm. For example, the distance d may be in the range of 25-250 μm, more preferably 100-200 μm. For example, the distance may be 100 μm or 200 μm. However, larger distances are also possible. For example, a distance up to 5 mm may be used. This distance defines the cavity depth of the retainer. A larger distance, i.e., cavity depth, will result in a thicker retainer, which in turn results in more weight to be carrier by the robot arm.

The cavity dimensions, in particular the distance between the exposure surface of the substrate and the counter surface, has been seen to be of importance to the CVD process. The value of this distance has been seen to enable prevention of metal atoms, such as copper atoms, from escaping from the cavity, which might cause a net evaporation. By the set distance, which is very small in comparison with the area of the exposure surface and the counter surface, most of the metal atoms will be redeposited or reabsorbed onto the exposure surface, and not lost. Some metal atoms may still be lost due to evaporating through the sides of the cavity which are open. This loss has however been seen to be negligible, or at least sufficiently small, on the time scale of the LP-CVD process. The side of the cavity is open to allow process gas to diffuse into the cavity to allow for graphene growth.

Further, also the roughness of the counter surface is assumed to influence the chemical reactions occurring during the CVD process. The roughness of the surface is assumed to influence the result of impacts between the precursor molecules and/or evaporated metal atoms, thereby influencing their mean free path in the cavity and the distance travelled before (re) absorbing onto the exposure surface.

Hence, the distance between the exposure surface and the counter surface, and likely also the roughness of the counter surface, will influence the reactions during CVD and the resulting film formed.

The retainer may further comprise at least one inlet provided between the first surface and the second surface, the inlet configured for introducing one or more process gases into the retainer. That is, the inlet allows for introduction of precursor gases in the reaction cavity which is formed when an exposure substrate is positioned on the retainer. The inlet may be provided in the form of one or more openings.

Hence, the retainer provides an entrance path for the precursor gases. At the same time, as described above, the dimensions of the cavity are designed such that metal atoms with high probability sublime back to the exposure surface, rather than escaping out of the cavity.

The second surface may advantageously be formed by a plurality of ledges protruding from a main body of the retainer, the main body comprising the first surface. Preferably, three ledges are provided, providing stability of the substrate. Alternatively, other forms of support elements, protruding from the main body and forming support surfaces for the substrate, may be provided. What is important is that the second surface, which forms the support on which the substrate rests during CVD processing, is at a well-defined distance from the counter surface. Preferably, the exposure surface of the substrate is substantially parallel with the counter surface.

The third surface may be formed by an edge protruding from at least one of the ledges, or second surfaces. Preferably, the third surface may be formed by an edge protruding from each of the ledges or second surfaces.

The at least one edge, formed by the third surface, prevents or confines movement of the substrate, in particular in a horizontal direction, i.e., in a direction parallel to the counter surface.

The second and third surfaces, i.e., the ledges and the edges, are preferably substantially uniformly distributed around a periphery of the counter surface.

The retainer may comprise, or be formed of, quartz. The counter surface may hence be a quartz surface.

Quartz is conventionally used in various applications in semiconductor manufacturing and processing. Quartz has many advantages, including high availability, available in the form and dimensions of semiconductor wafers, at relatively low costs. It is also relatively easy or at least straightforward to machine. Processing such as sandblasting can be applied for bulk removal of material, e.g. to pre-shape the quartz body. Subsequently, other processes, such as laser micromachining, can be applied to shape the retainer with high precision, and/or to provide smooth surfaces.

Furthermore, quartz has a low thermal expansion coefficient, whereby even at the high temperatures applied during LP-CVD processes the stresses and strains in the quartz body will be low. Quartz has been observed to be able to withstand a high number of temperature cycles up to the temperatures used in graphene production by CVD, e.g., up to around 1000° C., followed by cooling down to room temperature. Thereby, the retainer as presented herein can be re-used through many cycles of CVD processing.

The retainer may be a monolithic structure. That is, the counter surface, the second surface and the third surface may be formed by machining a quartz body, and formed in one piece from the quartz body.

Alternatively, the retainer may comprise:
a main body comprising the first surface, wherein the first surface comprises the counter surface and a groove at least partially surrounding the counter surface; and
a set of support elements configured to be positioned in the groove, the support elements forming the second surface and the third surface.

The support elements may be provided in various dimensions, to thereby allow substrates of varying dimensions to be supported by the retainer.

Further alternatively, the retainer may comprise:
a main body comprising the first surface, wherein at least a part of the first surface forms the counter surface, a set of first cut-outs and a set of second cut-outs, the second cut-outs offset from the first cut-outs; and
a set of first support elements configured to be positioned in the first cut-outs, the first support elements defining the second surface; and
a set of second support elements configured to be positioned in the second cut-outs, the second support elements defining the third surface.

The first support elements and the second support elements are preferably substantially uniformly distributed along a circumference of the counter surface.

The first support elements and the second support elements form separate support elements for supporting, or carrying, the exposure substrate and for delimiting lateral movement thereof. By the separation of the two functions in the embodiment wherein the retainer is not formed as a monolithic structure but formed by separate support elements, the complexity and costs of manufacturing may be reduced in comparison to using the same support elements for both functions.

The substrate may comprise a sapphire substrate provided with an epitaxial metal layer forming the exposure surface. The metal layer is generally a thin metal film. The metal may be selected from one or more of copper (Cu), nickel (Ni), a nickel-copper (NiCu) alloy, platinum (Pt), etc. The epitaxy of the metal film renders the exposure surface suitable for growth of graphene thereon. This has been seen to provide an easy to handle substrate, enabling formation of large area high quality graphene.

However, the thermal expansion coefficient of sapphire is different from that of quartz, which is preferably used for the retainer. The substrate will therefore experience different thermal expansion, i.e., expand more, than the retainer. This can be accounted for by setting the dimensions of the retainer, in particular the positions of the ledges and the edges, as described in the next paragraphs.

Preferably, the retainer may comprise a plurality of edges, wherein the edges are located to allow the substrate to thermally expand during the CVD process while still providing a mechanical interface between the edges and a circumferential edge of the substrate.

The mechanical interface relates to, i.e. may be implanted as, a distance between the edges and the circumferential edge of the substrate. It may also be referred to as “play” or mechanical “play”.

That is, the second and third surfaces are preferably positioned and dimensioned such as to allow for thermal expansion of the substrate during CVD processing, without the substrate becoming clamped and/or fixated in the retainer. That is, the ledges, or other support elements forming the second surface, are positioned and/or dimensioned such that a distance is realized between the edge, formed by the third surface, and the lateral edge of the substrate. The distance, also referred to as play, may be designed, or calculated, such as to retain the substrate in the retainer during handling, e.g., by a robot moving the retainer with the substrate thereon, between different stations in a system, such as in a semiconductor fab, while allowing the substrate to thermally expand due to the high temperatures to which it is exposed during the CVD process, without being exposed to stress or strain caused by mechanical clamping of the substrate.

The positions and dimensions referred to herein above can be set by designing the retainer to correspond to the dimensions of the substrate(s) to be supported by the retainer.

The retainer can be scaled and/or otherwise configured to support substrates having dimensions according to various known semiconductor wafer dimensions.

The retainer is particularly advantageous in low pressure chemical vapor deposition, LP-CVD, processes and systems.

Hence, in summary, according to the first aspect, a substrate retainer is provided, which performs multiple functions, including carrying the substrate and forming a counter surface. The retainer facilitates a straightforward way of implementing the retainer in a substrate CVD processing system for forming graphene layers, as well as in other types of semiconductor processing.

The retainer enables easy and quick positioning of the substrate on the retainer, at a well-defined and highly accurate distance from the counter surface.

Furthermore, the retainer may advantageously be shaped and dimensioned such as to allow handling of it by conventional wafer handling robots used in semiconductor manufacturing. In particular, the retainer is formed such as to be held by the robot arm of conventional wafer handling robots, to fit in storage racks such as wafer cassettes, and to be positioned and raised/lowered by lift pins and other substrate positioning mechanisms provided in processing, transfer, and/or storage chambers in a (vacuum) system of a semiconductor fab.

According to a second aspect, a stack is provided, comprising the retainer of the first aspect and a substrate comprising an exposure surface, the retainer supporting the substrate on the second surface with the exposure surface facing the counter surface.

As described herein above, the retainer is advantageously dimensioned and formed to allow handling by conventional semiconductor wafer handling robots. The retainer may be provided with elements, as known in the field of semiconductor fabrication, allowing the retainer to be held and moved by arms of such robot. This enables implementation and use of the stack, formed by the retainer and the substrate, in existing processing systems and facilities, such as a semiconductor fab.

As described herein above with respect to the first aspect, the substrate may be a sapphire substrate provided with an epitaxial metal layer, the epitaxial metal layer forming the exposure surface. The substrate may have dimensions of a semiconductor wafer.

According to a third aspect, a method of fabricating a retainer for holding a substrate is provided, the method comprising:
providing a main body having a first surface;
forming a counter surface on the first surface;
forming a second surface substantially parallel to the counter surface and arranged at a distance, d, from the counter surface, the second surface configured for supporting the substrate;
forming a third surface, arranged at an angle to the second surface for forming an edge for confining movement of the substrate;
wherein the step of forming a counter surface comprises:
a first processing step to form a distance, d, between the second surface and the portion of the first surface which is to form the counter surface;
a second processing step applied to the portion of the first surface, the second processing step comprising reducing a roughness of the portion of the first surface resulting after the first processing step.

The first processing step may comprise a materials removing technique, such as sandblasting. Thereby, a cavity may be formed in the main body.

The second processing step may comprise a polishing process, for example laser patterning, such as laser micromachining.

In particular, the retainer formed by the method of the third aspect forms a monolithic structure.

According to a fourth aspect, a method of fabricating a retainer for holding a substrate is provided, the method comprising:
providing a main body having a first surface;
forming a counter surface on the first surface;
forming a second surface substantially parallel to the counter surface and arranged at a distance, d, from the counter surface, the second surface configured for supporting the substrate;
forming a third surface, arranged at an angle to the second surface for forming an edge for confining movement of the substrate;
wherein the step of forming a counter surface comprises:
forming a groove at least partially surrounding the portion of the first surface;
placing a plurality of support elements in the groove, each of the support elements comprising the second surface, and at least one of the support elements further comprising the third surface.

By the method of the fourth aspect, the counter surface may be formed of a substantially unprocessed surface of the quartz material, without applying a materials removal technique to the portion of the first surface forming the counter surface.

Machining, e.g. according to the first and, eventually, second mechanical processing steps described in relation to the method of the third aspect, may be required only for forming the groove in which the support elements are positioned and/or mounted.

The support elements may be permanently or removably positioned in the groove. Support elements of different dimensions may be provided, to facilitate the retainer to be adaptable to substrates of different dimensions.

The retainer manufactured by any of the methods according to the third and fourth aspects may advantageously be a retainer according to the various embodiments of the first aspect.

Hence, in summary, the invention relates to a retainer for holding a graphene growth substrate for processing in a cassette-to-cassette automated CVD system. The system is designed to load wafers from a cassette into a loadlock chamber and from that loadlock chamber into a process chamber. In the process chamber graphene is grown by a CVD process on these wafers at high temperatures. When using Cu as exposure surface, the temperature during CVD is generally between 800° C. and 1088° C. When using Ni as exposure surface, the temperature is generally between 600-1200° C. After that the wafer is unloaded into the loadlock and subsequently into cassette.

Graphene is preferably grown on epitaxial sapphire substrates with between 500 and 2000 nm of Cu deposited onto the sapphire. Copper however suffers from significant evaporation at typical growth temperatures for graphene. To prevent the Cu from evaporating from the surface several approaches have been implemented in other systems (tube furnaces rather than cassette to cassette systems), such as putting Cu foil in an enclosure, folding a copper foil or providing a counter surface.

According to the present disclosure, a counter surface is implemented, with multiple functionalities at the same time. The implementation may preferably be a quartz wafer that is machined to support a sapphire/Cu substrate that is placed upside down on three ledges machined into the quartz substrate.

The quartz substrate may be a 200 mm quartz wafer that fits on the robot arm, the cassette and the lift pin mechanism and heaters in the process chamber. At the same time the structure of the ledges prevents the wafer from shifting while the retainer wafer stack is moved on the robot. The distance between the substrate exposure surface and the counter surface is such that net evaporation from the epitaxial metal layer on the exposure surface is negligible. The distance, i.e., the cavity depth, prevents metal atoms, such as copper, from evaporating from the substrate as most of the copper is redeposited and not lost.

In this application, the term “retainer” is to be understood as a structure retaining the substrate during CVD processing, preferably also prior and/or after CVD processing. It may also be referred to as substrate holder, substrate carrier, or substrate susceptor.

The term “substrate” is to be understood as an element provided with the surface onto which the graphene layer or film is to be formed. It may also be referred to as wafer.

### BRIEF DESCRIPTION OF THE DRAWINGS

Further features and advantages of the invention will become apparent from the description of the invention by way of non-limiting and non-exclusive embodiments. These embodiments are not to be construed as limiting the scope of protection. The person skilled in the art will realize that other alternatives and equivalent embodiments of the invention can be conceived and reduced to practice without departing from the scope of the present invention. Embodiments of the invention will be described with reference to the figures of the accompanying drawings, in which like or same reference symbols denote like, same or corresponding parts, and in which:

FIG. 1a shows a schematic cross section of a retainer supporting a substrate, according to a first embodiment;

FIG. 1b shows a schematic top view of the retainer according to the first embodiment;

FIG. 2a shows a cross section of retainer according to a second embodiment;

FIG. 2b shows a schematic top view of a main body of the retainer of the second embodiment;

FIG. 3 shows a cross section of retainer according to a third embodiment.

FIGS. 4a, 4b and 4c schematically illustrate features of a retainer according to a fourth embodiment;

FIG. 5 shows a schematic illustration of a system for chemical vapor deposition.

### DESCRIPTION OF EMBODIMENTS

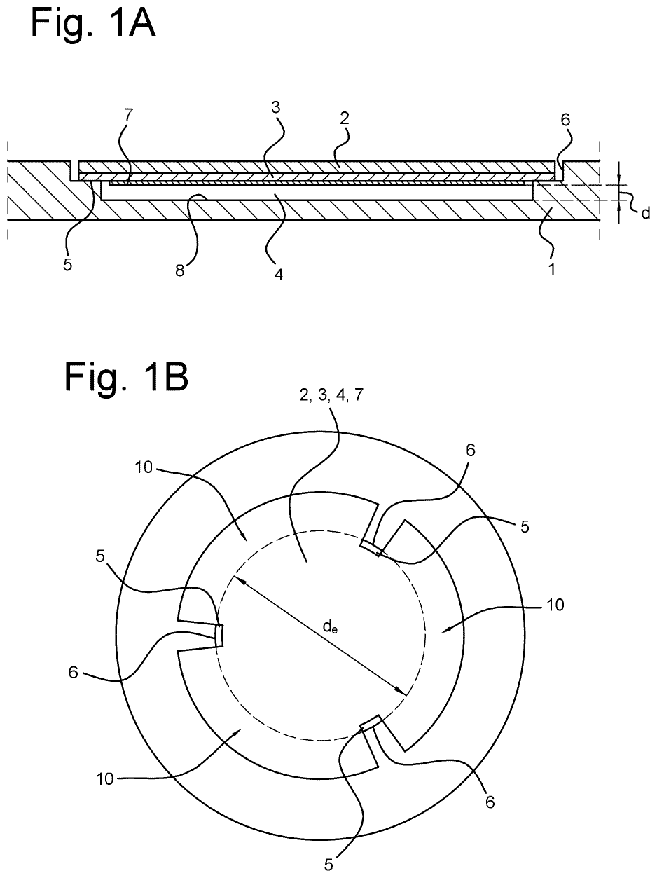

FIGS. 1A and 1B shows a non-limiting embodiment of the retainer according to a first embodiment. FIG. 1A shows a cross section of a stack formed by the retainer 1 carrying the substrate 2. FIG. 1B shows a top view of the retainer 1, with the substrate 2 indicated with the dashed line.

According to the first embodiment, the retainer 1 is formed of a monolithic structure. As described above, the retainer 1 may be formed of a monolithic quartz body. In the quartz body, a recess is machined, whereby a second surface 5, forming a ledge or support surface for the substrate 2, is formed. When the substrate 2 is supported by the retainer, a cavity 4 is formed.

Although FIG. 1A might suggest that the ledges 5 and edges 6 are located 180° opposite one another, this is shown as such mainly for illustration of the concept, whereas preferably the ledges and edges are arranged 120° degrees apart, since three of them are preferably provided.

For manufacturing graphene in a LP-CVD process, the substrate 2 is typically provided with a metal film 3. For example, the substrate 2 may be a sapphire substrate, on which an epitaxial copper film has been formed. The metal film 3 is provided to form an exposure surface having surface properties, such as atomic lattice, suitable for graphene growth.

In the cavity, a first surface is formed, forming a counter surface 8, which is located at a distance d from the second surface formed by the ledges 5. The distance d can be formed with high accuracy.

The cavity 4 forms a reaction cavity, wherein the CVD process takes place to form the graphene film 7.

FIG. 1B shows a schematical illustration of the retainer according to the first embodiment, as seen from above. As can be seen in FIG. 1B, preferably three ledges 5 and edges 6 are provided, which are substantially uniformly distributed around the counter surface. As can also be seen, one or more inlet 10 are provided for introducing precursor gases into the cavity 4. Such precursor gases may typically comprise methane, CH₄, ethane, C₂H₆, or other carbon containing gases.

The retainer is further dimensioned, in relation to the dimensions of the substrate 2, which advantageously has the dimensions of a conventional semiconductor wafer, as to allow the substrate 2 with the copper film 3 to thermally expand due to the temperatures applied during the CVD process.

Advantageously, the retainer is dimensioned such that a diameter, de, of a virtual circle defined by the edges 6 is of a dimension such that there will be a distance, also referred to as play, or interface, p, between the edges of the substrate and the edges 6 even when the substrate experiences its maximum thermal expansion during the CVD process.

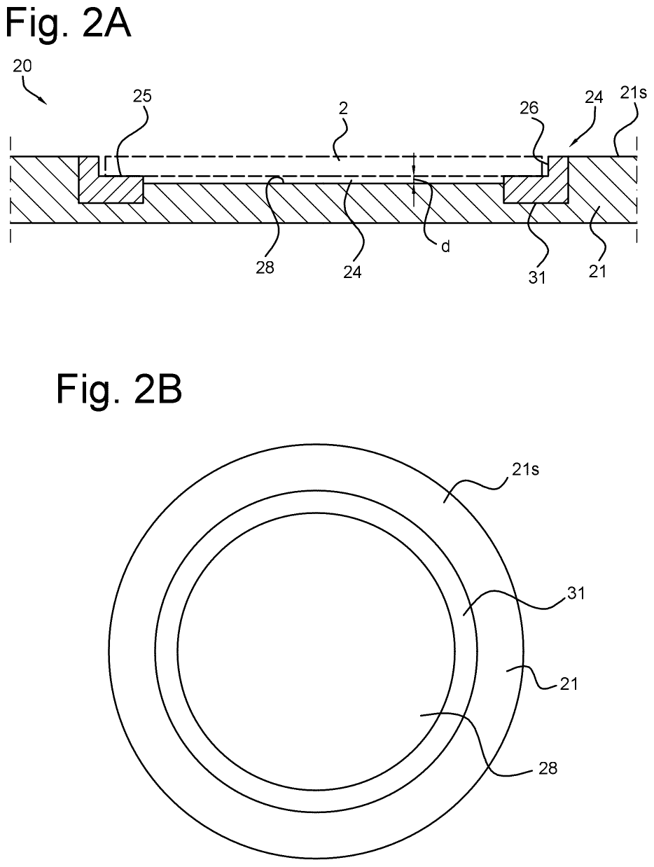

FIGS. 2A and 2B show a retainer 20 according to a second embodiment. Contrary to the retainer 1 according to the first embodiment, the retainer 20 according to the second embodiment is not a monolithic structure, but comprises a main body 21 and a plurality of support elements 29, arranged in a groove 31 formed in a surface 21s of the main body. The support elements 29 comprise a second surface, or ledge, 25, and a third surface, or edge, 26, corresponding in function to the ledge 5 and edge 6 of the retainer 1 shown in FIGS. 1A and 1B. The substrate 2, provided with an epitaxial layer 3, indicated by the dashed line, is supported by the retainer 20 in similar manner as by the retainer 1 shown in FIGS. 1A and 1B.

FIG. 2B shows a schematic top view of the main body 21 of the retainer. As can be seen, the groove 31 is machined into the surface 21s of the main body. Although FIG. 2B shows the groove 31 as a full circle surrounding the counter surface 28, it is not necessary that the groove 31 is provided as a full circle. Alternatively, the groove 31 may be formed as a plurality, e.g. at least three, semicircles uniformly distributed around the counter surface 28.

According to the second embodiment, the counter surface 28 can be formed as a part of the surface 21s of the quartz main body, without requiring materials removal. This may lead to a smoother counter surface 28 than the counter surface 8 of the first embodiment, which has been formed through a materials removing technique. It is expected that the smoothness of a counter surface 8, 28 may influence the behavior of atoms and/or molecules present within the cavity 4, 24, in particular their behavior upon and resulting from collisions with the counter surface.

The plurality of support elements 29 can be provided with different dimensions, e.g. different dimensions of the second surface area 25, to thereby enable accommodating substrates of different sizes on the retainer.

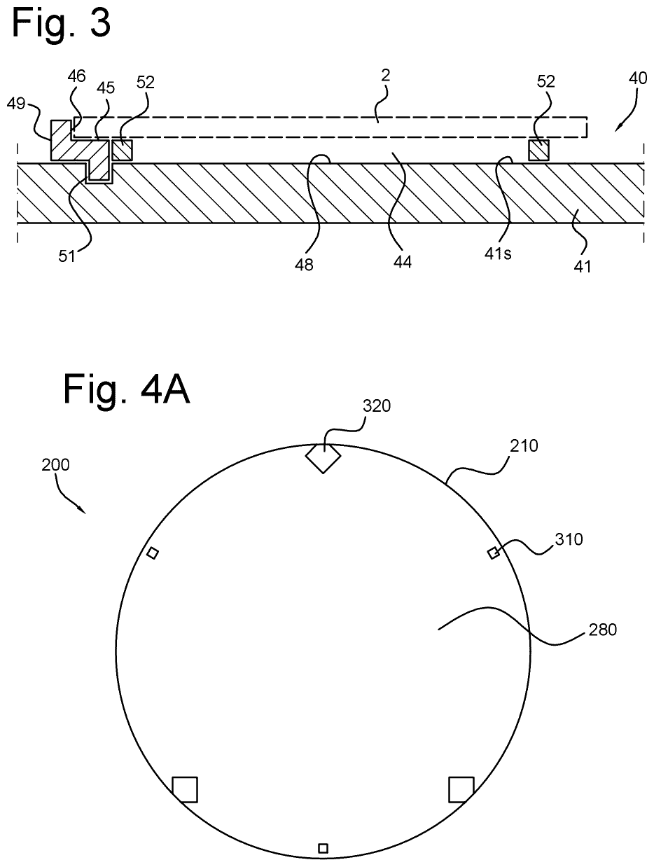

FIG. 3 shows a schematic cross section of a retainer 40 according to a third embodiment. The retainer of the third embodiment has many similarities with the retainer of the second embodiment, shown in FIGS. 2A and 2B, and will therefore not be described in all detail herein. Similar to the retainer 20 of the second embodiment, the retainer 40 is not monolithic, but formed of a main body 41, at least one support element 49, and a plurality of additional support elements 52. The at least one support element 49 provides the second surface 45 and the third surface 46, i.e., an edge and a ledge. The at least one support element 49 is arranged in a groove 51 formed in the surface 41s of the main body. The edge 46 of the support element 49 hence forms an edge confining lateral movement of the substrate 2. In addition, additional support elements 52 are provided, forming a second surface on which the substrate 2 rests. While FIG. 3 indicates that the retainer 40 comprises one support element 46 and three additional support elements 52, these may be provided in different numbers, as long as the substrate rests on the retainer by means of gravity and forming a well-defined, highly accurate distance between the exposure surface 3 of the substrate and the counter surface 48.

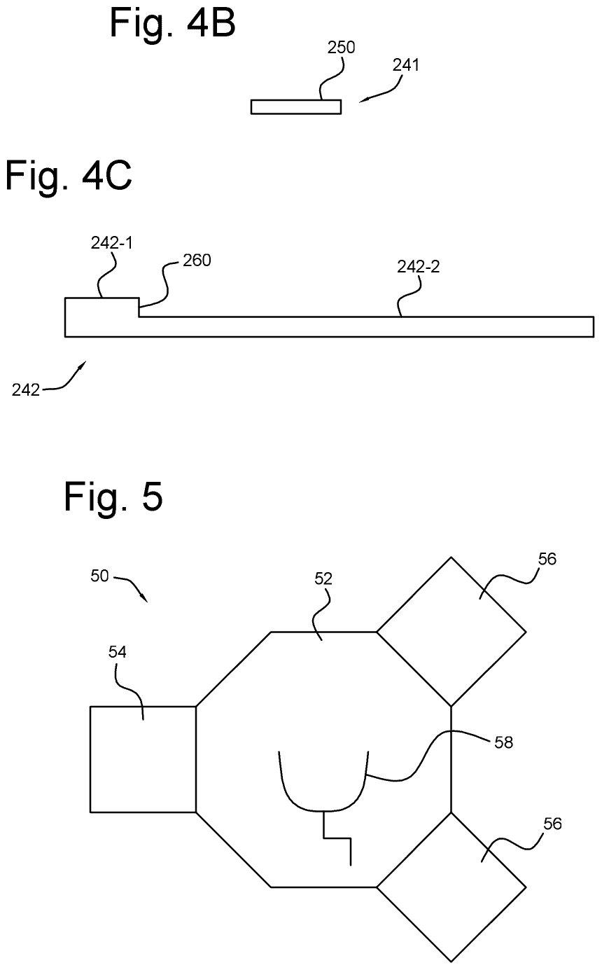

FIGS. 4A, 4B and 4C shows a schematic illustration of a retainer 200 according to a fourth embodiment. The concept resembles that of the second embodiment illustrated in FIGS. 2A and 2B, with the main difference that the functions of (horizontally) supporting the exposure substrate 2 and of constraining lateral movement or displacement of the substrate 2 are separated, and achieved by two different types of support elements: a first support element, 241 and a second support element 242, respectively.

FIG. 4A shows a schematic top view of the retainer main body 210. As can be seen, this is provided with three cut-outs 310, formed in its upper surface, for receiving the first support elements 241, and three additional cut-outs 320, also formed in its upper surface, for receiving the second support elements 242.

As can be seen, the first cut-outs 310 and the second cut-outs 320 are all substantially uniformly distributed around the circumference of the counter surface. Preferably, the first cut-outs and the second cut-outs, and hence the first support elements 241 and the second support elements 242, are offset with respect to one another.

In the embodiment shown in FIG. 4A, the retainer is configured for supporting an exposure substrate 2 having a diameter corresponding, i.e., the same, as that of the main body 210 of the retainer. This will mean that part of the second support elements 242, which are fitted into the second cut-outs 320, will protrude with their thicker portion 242-1 laterally outside the main body 210 of the retainer. However, the second support elements can be positioned such as not to interfere with the robot handling of the retainer 200.

FIG. 4B schematically shows the first support element 241 in a side view. The first support element 241, which may be formed as a rectangular or cubical block, is positioned into a cut-out 310 provided in the retainer main body 210. The height of the first support element 241 in combination with the depth of the cut-out 310 defines the distance d between the counter surface 280 formed by an upper surface of the main body 210 and an upper surface 250 of the first support element, the upper surfaces 250 of the first support elements 241 forming the second surface. The first support elements 241, together with the first cut-out 310, hence define the cavity depth of the reaction cavity formed in the retainer when carrying the exposure substrate.

Since the first support element 241 together with the first cut-out 310 define the cavity depth, i.e., the distance between the exposure surface and the counter surface, the first support element and the first cut-out should be manufactured with high precision. In particular, their horizontal surfaces should be smooth, such as to provide surfaces having low roughness. The first support elements may advantageously be machined through a materials removal or polishing technique such as laser micromachining.

FIG. 4C schematically shows the second support element 242, in a side view. The second support element may be formed substantially in an L-shape, wherein the thicker portion, 242-1, defines the third surface 260, configured to delimit or restrain lateral movement of the exposure substrate 2, in the same manner as described herein above with respect to the first and second embodiments. The thickness of thicker portion 242-1 of each second support element 242, defining the vertical dimension of the third surface 246, is high enough to be sufficient for restraining lateral movement of the exposure substrate 2. The depth of the second cut-out 320 together with the thickness of the thinner portion 242-2 of the support element 242, are such that a distance between the upper surface of portion 242-2 and the counter surface 280 is preferably lower than the distance d between the second surface 250 and the counter surface 280, such that the exposure substrate 2 is fully supported by the second surface 250 and hence the exposure surface is at a well-defined distance to the counter surface 280. At most, it may be flush with the second surface 250.

The second support elements 242 hence are not responsible for setting the cavity distance. Therefore, the second support elements may be manufactured with lower accuracy than the first support elements, as the accuracy of their dimensions, in particular the requirements as to low roughness of their surfaces, are lower than for the first support elements. Therefore, the second support elements 242 may be manufactured using a materials removal technique such as sandblasting.

Hence, separating the function of supporting the substrate and of restraining lateral displacement thereof, may lead to a less complex process of manufacturing the retainer.

FIG. 5 shows a schematic top view of a LP-CVD system, which may be any conventional LP-CVD. The system comprises a load-lock 52, also referred to as transfer chamber and/or parking chamber, enabling wafers to be transferred between a wafer cassette 54 and a CVD processing chamber 56, through load-lock 52. The wafer can be moved between the cassette, an intermediate position in the load-lock, and the processing chamber by a robot 58, also referred to as a wafer handling robot.

The processing chamber 56 may comprise various components as known in the field of (low pressure) chemical vapor deposition, such as one or more heaters for heating the substrate, gas inlets, vacuum pumps, etc. Such components are described in WO 2014/033282 A1.

As can be understood from the above, the retainer according to the different embodiments described herein above has dimensions corresponding to a semiconductor wafer, and can therefore be positioned in the wafer cassette 54, lifted and moved by the robot 58, and positioned on lift pins and/or other wafer carrier means provided in the processing chamber 56 and known in the art.

Hence, as follows from the above, the retainer according to the present disclosure forms a robust, passive support for a substrate to be exposed to a LP-CVD process, in particular for forming a graphene layer, wherein through the design of the retainer a well-defined distance is formed between the exposure surface of the substrate and the counter surface of the retainer. Thereby, net evaporation of metal atoms from the exposure surface, such as copper, can be prevented or at least limited. Further, the retainer is of such shape, weight and dimensions to resemble conventional semiconductor wafers and wafer carries, thereby enabling the stack formed by the retainer and the substrate to be used in an existing low pressure chemical vapor deposition, LP-CVD, system and other semiconductor manufacturing facilities, substantially without modification or alteration thereof.

The invention hence provides a passive way of preventing Cu evaporation by creating an opposing surface, herein referred to as counter surface, at a defined distance from the surface of the epitaxial metal layer of the substrate.

One could think of a movable counter surface that is brought close to the wafer surface mechanically prior to heating up the surface, but that would mean designing a system with movable parts and micron accuracy that can function in heat cycles of 1000° C. up and down. By doing this in a passive way as described herein, the inventors have circumvented having to solve that problem.

At the same time, the structure of the retainer has been machined into a quartz wafer which allows using the regular ways of handling the stack (quartz retainer+sapphire/Cu) on a robot arm and storing it in a cassette. The cassette can be a commercially available cassette, selected to be of a type having slots with dimensions allowing handling of the stack formed by the retainer and the substrate.

The structure of the retainer has been designed to allow for differences in thermal expansion between quartz and sapphire. Since Sapphire expands more than quartz space to allow for expansion of the sapphire substrate has been accounted for within the quartz structure. At the same time the sapphire cannot move more than is required to allow for the thermal expansion, to keep it in place. If an exact fit would have been provided, sapphire could break upon thermal expansion.

Quartz is preferably used as the material because quartz has a low coefficient of thermal expansion (CTE). Therefor heat cycling quartz by cycles of 1000° C. does not lead to large stresses in the material, also the material is more tolerant to heat uniformity variations that can cause additional stress leading to material breakage. The quartz as a material does not interfere with the graphene growth process. Additionally, it is readily and cheaply available in the form of high purity wafers.

It will be clear to a person skilled in the art that the scope of the invention is not limited to the examples discussed in the foregoing, but that several amendments and modifications thereof are possible without deviating from the scope of the invention as defined in the attached claims. While the invention has been illustrated and described in detail in the figures and the description, such illustration and description are to be considered illustrative or exemplary only, and not restrictive. The present invention is not limited to the disclosed embodiments but comprises any combination of the disclosed embodiments that can come to an advantage.

For example, although not described in detail above, the retainer may be configured to support more than one substrate. That is, the retainer may be provided with a plurality of substrate support areas, each including a cavity, a counter surface, second and third surfaces or ledges and edges, according to the embodiments described herein above. That is, seen from a top view, the plurality of substrates supported by the retainer may be arranged to form a portion of hexagonal surface lattice arrangement or a fcc surface lattice structure.

Variations to the disclosed embodiments can be understood and effected by a person skilled in the art in practicing the claimed invention, from a study of the figures, the description and the attached claims. In the description and claims, the word “comprising” does not exclude other elements, and the indefinite article “a” or “an” does not exclude a plurality. In fact it is to be construed as meaning “at least one”. The mere fact that certain features are recited in mutually different dependent claims does not indicate that a combination of these features cannot be used to advantage. Any reference signs in the claims should not be construed as limiting the scope of the invention. Features of the above described embodiments and aspects can be combined unless their combining results in evident technical conflicts.

1. A retainer for holding a substrate during chemical vapor deposition, CVD, processing, the retainer comprising:
a first surface configured to form a counter surface relative to an exposure surface of the substrate;
a second surface, substantially parallel to the counter surface and arranged at a distance, d, from the counter surface, the second surface arranged for supporting the substrate;
a third surface, arranged at an angle to the second surface, the third surface forming an edge for confining movement of the substrate.

2. The retainer according to claim 1, configured such that a reaction cavity is formed between the exposure surface of the substrate and the counter surface when the substrate is supported by the retainer.

3. The retainer according to claim 1, wherein at least one inlet is provided between the first surface and the second surface, the inlet configured for introducing one or more precursor gases into the retainer.

4. The retainer according to claim 1, wherein the second surface is formed by a plurality of ledges protruding from a main body of the retainer, the main body comprising the first surface.

5. The retainer according to claim 4, wherein the edge protrudes from at least one of the ledges.

6. The retainer according to claim 1, wherein the retainer comprises quartz.

7. The retainer according to claim 1, wherein the retainer is a monolithic structure.

8. The retainer according to claim 1, wherein the retainer comprises:
a main body comprising the first surface, wherein the first surface comprises the counter surface and a groove at least partially surrounding the counter surface;
a set of support elements configured to be positioned in the groove, the support elements forming the second surface and the third surface.

9. The retainer according to claim 1, wherein the retainer comprises:
a main body comprising the first surface, wherein at least a part of the first surface forms the counter surface, a set of first cut-outs and a set of second cut-outs, the second cut-outs offset from the first cut-outs; and
a set of first support elements configured to be positioned in the first cut-outs, the first support elements defining the second surface; and
a set of second support elements configured to be positioned in the second cut-outs, the second support elements defining the third surface.

10. The retainer according to claim 1, wherein the distance, d, is in a range of 50-250 μm.

11. The retainer according to claim 1, comprising a plurality of edges, wherein the edges are located to allow the substrate to thermally expand during the CVD process while still providing a mechanical interface between the edges and a circumferential edge of the substrate.

12. A stack comprising the retainer according to claim 1, and a substrate comprising an exposure surface, the retainer supporting the substrate on the second surface with the exposure surface facing the counter surface.

13. The stack according to claim 12, wherein the substrate is a sapphire substrate provided with an epitaxial metal layer, the epitaxial metal layer forming the exposure surface.

14. The stack according to claim 12, wherein the substrate has dimensions of a semiconductor wafer.

15. Method for fabricating a retainer for holding a substrate, the method comprising:
providing a main body having a first surface;
forming a counter surface on the first surface;
forming a second surface substantially parallel to the counter surface and arranged at a distance, d, from the counter surface, the second surface configured for supporting the substrate;
forming a third surface, arranged at an angle to the second surface, the third surface forming an edge for confining movement of the substrate;
wherein the step of forming the counter surface comprises:
a first processing step to form the distance, d, between the second surface and the portion of the first surface which is to form the counter surface;
a second processing step applied to the portion of the first surface, the second processing step comprising reducing a roughness of the portion of the first surface resulting after the first processing step.

16. Method for fabricating a retainer for holding a substrate, the method comprising:
providing a main body having a first surface;
forming a counter surface on the first surface;
forming a second surface substantially parallel to the counter surface and arranged at a distance, d, from the counter surface, the second surface configured for supporting the substrate;
forming a third surface, arranged at an angle to the second surface, the third surface forming an edge for confining movement of the substrate;
wherein the step of forming a counter surface comprises:
forming a groove at least partially around a portion of the first surface which is to form the counter surface;
placing a plurality of support elements in the groove, each of the support elements comprising the second surface, and at least one of the support elements further comprising the third surface.
